(19) United States
(12) Patent Application Publication
(10) Pub. No.: US 2025/0167153 A1
(43) Pub. Date: May 22, 2025

(54) METHOD OF FORMING REDISTRIBUTION PAD AND METHOD OF MANUFACTURING SEMICONDUCTOR PACKAGE

(71) Applicant: Samsung Electronics Co., Ltd., Suwon-si (KR)

(72) Inventors: Okseon Yoon, Suwon-si (KR); Jinyoung Kim, Suwon-si (KR); Jiyoung Yoon, Suwon-si (KR); Kiseok Kim, Suwon-si (KR); Jihye Shim, Suwon-si (KR)

(21) Appl. No.: 18/932,984

(22) Filed: Oct. 31, 2024

(30) Foreign Application Priority Data
Nov. 20, 2023 (KR) 10-2023-0161027

(51) Int. Cl. H01L 23/00; G03F 7/028

(52) U.S. Cl. CPC H01L 24/19; G03F 7/028; H01L 2224/19

(57) ABSTRACT

A method of forming a redistribution pad, the method including forming a hole exposing a redistribution pattern in a redistribution insulating layer and forming a photoresist composition on a surface of the redistribution insulating layer and filling the hole. The photoresist composition including at least one first photoinitiator and at least one first crosslinking agent that cause a crosslinking reaction by a first light and at least one second photoinitiator and at least one second crosslinking agent that cause a crosslinking reaction by a second light having a different wavelength from the first light. The method further includes irradiating the first light to the photoresist composition, forming a photoresist pattern having a pattern hole using the photoresist composition to which the first light is irradiated, irradiating the second light to the photoresist pattern, and forming the redistribution pad using the photoresist pattern to which the second light is irradiated.

### CROSS-REFERENCE TO RELATED APPLICATION

This application is based on and claims priority under 35 U.S.C. § 119 to Korean Patent Application No. 10-2023-0161027, filed on Nov. 20, 2023, in the Korean Intellectual Property Office, the disclosure of which is incorporated by reference herein in its entirety.

### BACKGROUND

Aspects of the inventive concept relate to a method of forming a redistribution pad and a method of manufacturing a semiconductor package. More specifically, aspects of the inventive concept relate to a method of forming a redistribution pad using a single photoresist pattern and a method of manufacturing a semiconductor package.

According to the development of the electronics industry and consumer demands, electronic devices have been miniaturized and made light in weight. As electronic devices become miniaturized and made light in weight, semiconductor packages included in electronic devices are also miniaturized and made light in weight, and semiconductor packages are also required to be highly integrated and have a high speed. According to these demands, wiring pads that electrically connect semiconductor devices included in semiconductor packages and wiring structures are also being miniaturized. Accordingly, there is a demand for technology that may easily form miniaturized wiring pads.

### SUMMARY

Aspects of the inventive concept provide a method of forming a redistribution pad and a method of manufacturing a semiconductor package that may be easily formed and provide a redistribution pad with improved structural reliability.

According to an aspect of the inventive concept, there is provided a method of forming a redistribution pad, the method including forming a hole exposing a redistribution pattern in a redistribution insulating layer, forming a photoresist composition on a surface of the redistribution insulating layer and filling the hole, the photoresist composition including at least one first photoinitiator and at least one first crosslinking agent that cause a crosslinking reaction by a first light and at least one second photoinitiator and at least one second crosslinking agent that cause a crosslinking reaction by a second light having a different wavelength from the first light irradiating the first light to the photoresist composition, forming a photoresist pattern having a pattern hole using the photoresist composition to which the first light is irradiated, irradiating the second light to the photoresist pattern, and forming the redistribution pad using the photoresist pattern to which the second light is irradiated.

According to another aspect of the inventive concept, there is provided a method of forming a redistribution pad, the method including forming a hole exposing a redistribution pattern in a redistribution insulating layer, forming a photoresist composition on a surface of the redistribution insulating layer and filling the hole, the photoresist composition including at least one first photoinitiator and at least one first crosslinking agent that cause a crosslinking reaction by a first light and at least one second photoinitiator and at least one second crosslinking agent that cause a crosslinking reaction by a second light having a different wavelength from the first light, irradiating the first light to the photoresist composition, forming a photoresist pattern having a pattern hole using the photoresist composition to which the first light is irradiated, forming a first metal layer constituting a first portion of the redistribution pad on the redistribution pattern using the photoresist pattern, irradiating the second light to the photoresist pattern, and forming a second metal layer and a third metal layer constituting a second portion of the redistribution pad on the first metal layer using the photoresist pattern to which the second light is irradiated.

According to another aspect of the inventive concept, there is provided a method of forming a redistribution pad, the method including forming a hole exposing a redistribution pattern in a redistribution insulating layer, forming a seed layer covering a surface of the redistribution insulating layer and a surface of the redistribution pattern exposed by the hole, forming, on the seed layer, a photoresist composition including at least one first photoinitiator and at least one first crosslinking agent that cause a crosslinking reaction by first light having a wavelength in a range from 355 nm to 375 nm, and at least one second photoinitiator and at least one second crosslinking agent that cause a crosslinking reaction by second light having a wavelength in a range from 390 nm to 450 nm on the seed layer, irradiating the first light to the photoresist composition, forming a photoresist pattern having the pattern hole using the photoresist composition to which the first light is irradiated, irradiating the second light to the photoresist pattern, and forming the redistribution pad including a first metal layer including copper, a second metal layer including nickel, and a third metal layer including gold using the photoresist pattern to which the second light is irradiated.

### BRIEF DESCRIPTION OF THE DRAWINGS

Embodiments will be more clearly understood from the following detailed description taken in conjunction with the accompanying drawings in which:

FIG. 1 is a flowchart illustrating a method of manufacturing a semiconductor package, according to embodiments;

FIG. 2 is a flowchart illustrating a method of forming a redistribution pad, according to embodiments;

FIGS. 3, 4, 5A, 5B, 6A, 6B, 7, 8A, 8B, and 9-13 are diagrams illustrating each step of a method of manufacturing a semiconductor package, according to embodiments;

FIG. 14 is a flowchart illustrating a method of forming a redistribution pad, according to embodiments; and

FIGS. 15 and 16 are diagrams illustrating each step of a method of forming a redistribution pad, according to embodiments.

### DETAILED DESCRIPTION OF THE EMBODIMENTS

Reference will now be made in detail to embodiments, examples of which are illustrated in the accompanying drawings. In the drawings, like reference numerals are used to like elements throughout the specification, and descriptions thereof will not be repeated.

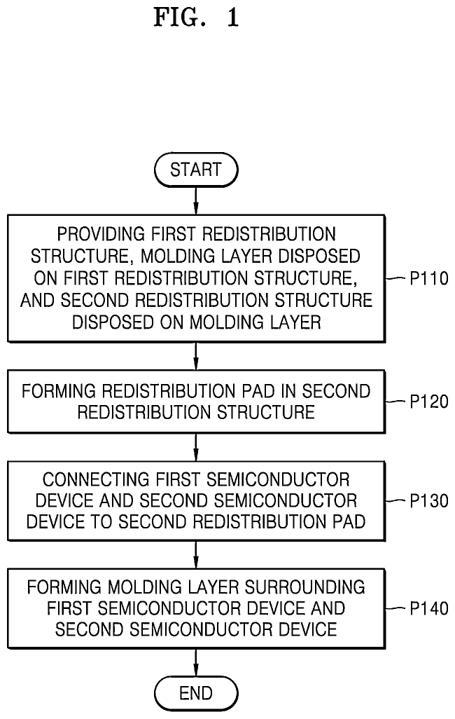

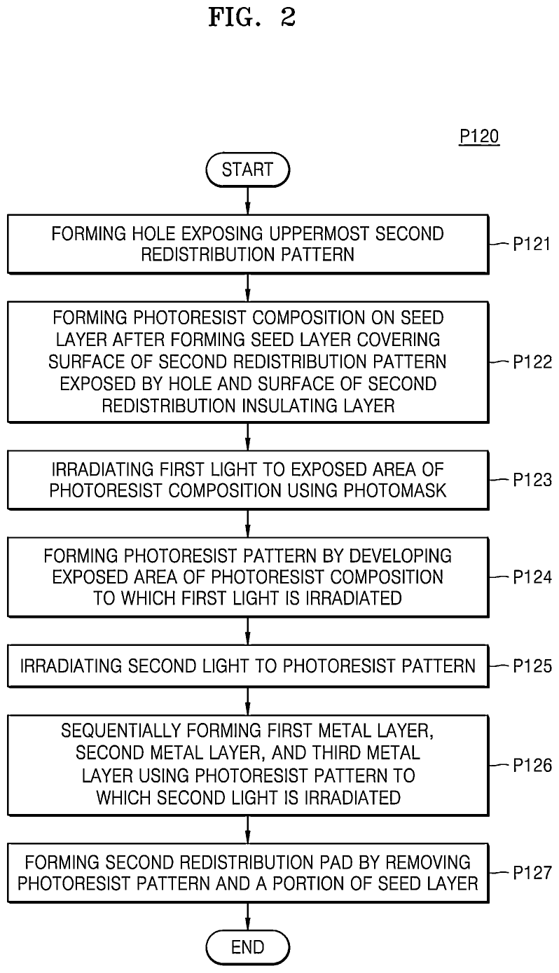

FIG. 1 is a flowchart illustrating a method of manufacturing a semiconductor package 10, according to embodiments. FIG. 2 is a flowchart illustrating a method of forming a redistribution pad 155 according to embodiments.

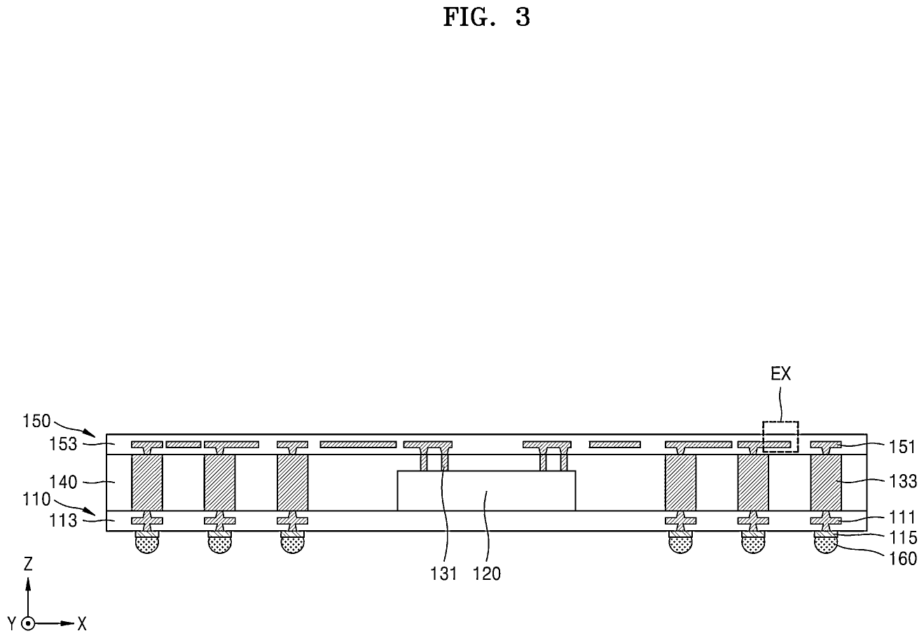

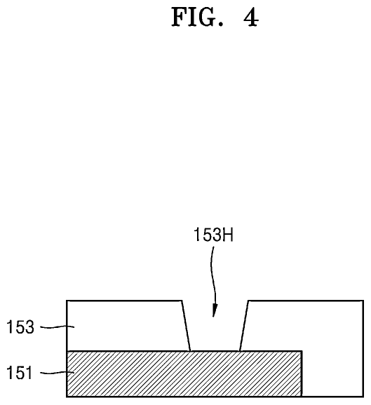

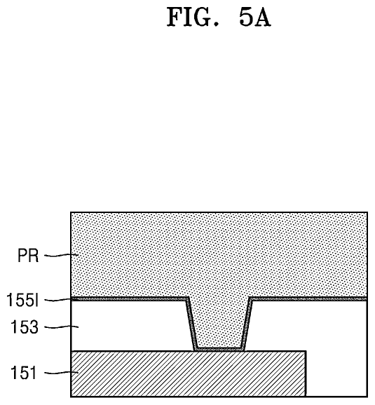

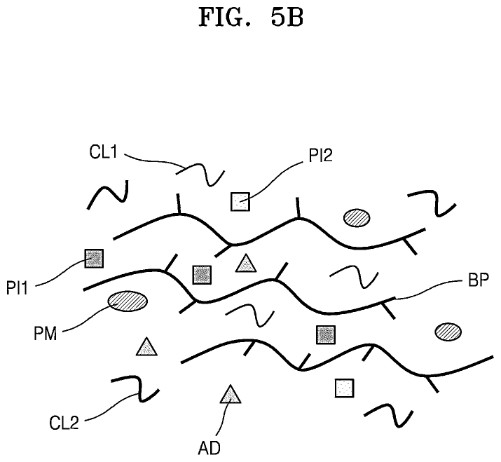

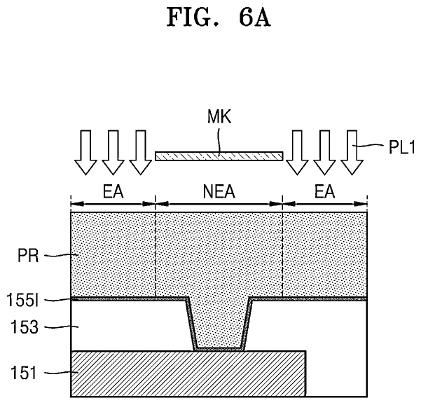

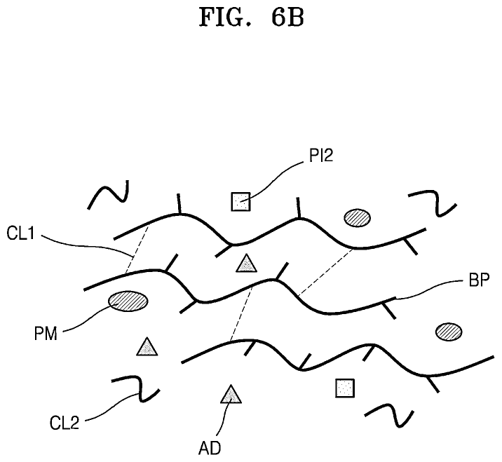

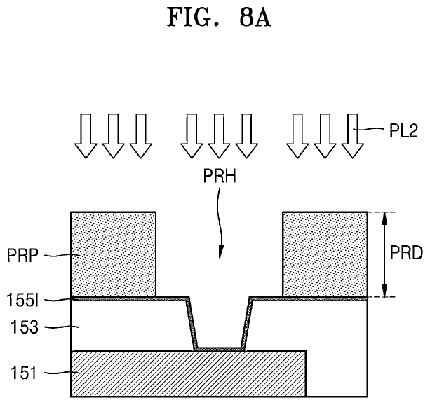

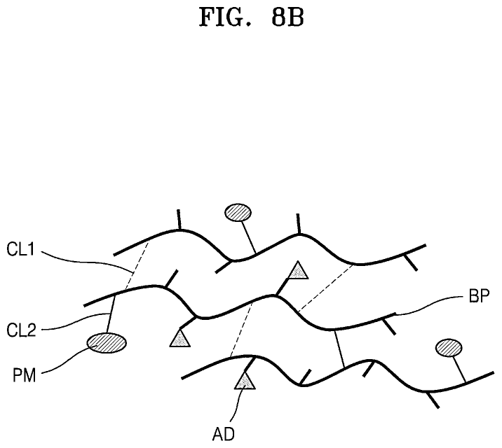

FIGS. 3, 4, 5A, 5B, 6A, 6B, 7, 8A, 8B, and 9-13 are diagrams illustrating each step of a method of manufacturing a semiconductor package, according to embodiments. Specifically, FIGS. 3 and 11-13 are cross-sectional views showing each step of a method of manufacturing a semiconductor package, according to embodiments; FIGS. 4, 5A, 6A, 7, 8A, 9, and 10 are enlarged cross-sectional views of a portion EX of FIG. 3; FIG. 5B is a conceptual diagram illustrating materials constituting a photoresist composition PR illustrated in FIG. 5A; FIG. 6B is a conceptual diagram illustrating materials constituting a photoresist composition PR of an exposed area EA to which first light PL1 illustrated in FIG. 6A is irradiated; and FIG. 8B is a conceptual diagram illustrating materials constituting a photoresist pattern PRP to which second light PL2 illustrated in FIG. 8A is irradiated.

Referring to FIGS. 1 and 3, a first redistribution structure 110, a second redistribution structure 150, and a first molding layer 140 may be provided (P110). Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

The first redistribution structure 110 may include a first redistribution pattern 111 and a first redistribution insulating layer 113. The first redistribution pattern 111 may include a plurality of first redistribution lines and a plurality of first redistribution vias. The first redistribution line may extend within the first redistribution insulating layer 113 in a horizontal direction parallel to an upper surface of the first redistribution insulating layer 113. Some of the first redistribution lines may be at different vertical levels from other portions of the first redistribution lines. The first redistribution via may extend within the first redistribution insulating layer 113 in a vertical direction (Z direction) perpendicular to the upper surface of the first redistribution insulating layer 113. The first redistribution via may connect the first redistribution lines at different vertical levels to each other or connect a portion of the first redistribution line located at the top of the first redistribution insulating layer 113 to a conductive post 133. For example, the first redistribution via may have a tapered shape in which a horizontal width of the first redistribution via increases in a direction from an upper surface of the first redistribution structure 110 to a lower surface of the first redistribution structure 110, but is not limited thereto.

In example embodiments, the first redistribution pattern 111 may include or may be formed of copper (Cu), titanium (Ti), titanium tungsten (TiW), titanium nitride (TiN), tantalum (Ta), tantalum nitride (TaN), and chromium. (Cr), aluminum (Al), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or a combination thereof.

The first redistribution insulating layer 113 may surround the first redistribution pattern 111. In an example embodiment, the first redistribution insulating layer 113 may include or may be formed of photo image-able dielectric (PID), Ajinomoto Build-up Film (ABF), solder resist (SR), epoxy molding compound (EMC), and FR-4, Bismaleimide Triazine (BT), or a combination thereof.

A plurality of first redistribution pads 115 may be disposed on a lower surface of the lowermost first redistribution pattern 111. The plurality of first redistribution pads 115 may include or may be formed of, for example, copper (Cu), aluminum (Al), silver (Ag), gold (Au), tungsten (W), titanium (Ti), or a combination thereof. The first redistribution via may connect a portion of the first redistribution line located at the bottom of the first redistribution insulating layer 113 to a first redistribution pad 115.

An external connection terminal 160 may be disposed on each of the plurality of first redistribution pads 115. The first redistribution structure 110 may be electrically connected to an external device through the external connection terminal 160. In example embodiments, each of the external connection terminals 160 may include or may be formed of tin (Sn), silver (Ag), copper (Cu), nickel (Ni), or a combination thereof. In example embodiments, each of the external connection terminals 160 may include a solder ball.

A bridge chip 120, a plurality of conductive posts 133, and the first molding layer 140 may be disposed on the first redistribution structure 110.

The bridge chip 120 may include a bridge substrate and a bridge circuit. For example, the bridge substrate may be a wafer including crystalline silicon, polycrystalline silicon, or amorphous silicon. The bridge circuit may be formed within the bridge substrate. The bridge circuit may be electrically connected to the second redistribution structure 150 through a plurality of metal pillars 131 disposed on an upper surface of the bridge chip 120. In example embodiments, the bridge circuit may include a buffer circuit capable of controlling a first semiconductor device 200 and a second semiconductor device 300. In other embodiments, the bridge circuit may include at least one selected from a transistor, diode, capacitor, and resistor.

The metal pillar 131 may contact the upper surface of the bridge chip 120 on a lower surface of the metal pillar 131, and may contact a second redistribution pattern 151 on an upper surface of the metal pillar 131. The plurality of metal pillars 131 may electrically connect the second redistribution structure 150 to the bridge chip 120.

The plurality of conductive posts 133 may be arranged on the first redistribution structure 110 and horizontally spaced apart from the bridge chip 120. For example, the bridge chip 120 may be disposed on the central area of the first redistribution structure 110, and the plurality of conductive posts 133 may be arranged on the edge area of the first redistribution structure 110 and horizontally spaced apart from the bridge chip 120. The plurality of conductive posts 133 may contact the first redistribution pattern 111 on a lower surface of the plurality of conductive posts 133 and may contact the second redistribution pattern 151 on the upper surfaces of the plurality of conductive posts 133. The plurality of conductive posts 133 may electrically connect the first redistribution structure 110 and the second redistribution structure 150.

The plurality of metal pillars 131 and the plurality of conductive posts 133 may have a cylindrical shape. However, aspects of the inventive concept are not limited thereto, and the plurality of metal pillars 131 and the plurality of conductive posts 133 may have a tapered shape in which a horizontal width thereof varies in the vertical direction (Z direction).

The horizontal width of each of the plurality of conductive posts 133 may be greater than the horizontal width of each of the plurality of metal pillars 131, but aspects of the inventive concept are not limited thereto.

In example embodiments, the plurality of metal pillars 131 and the plurality of conductive posts 133 may each include copper (Cu), aluminum (Al), silver (Ag), gold (Au), tungsten (W), and titanium (Ti), or a combination thereof.

The first molding layer 140 may surround the bridge chip 120 and the plurality of conductive posts 133 on the first redistribution structure 110. The first molding layer 140 may include, for example, thermosetting resin, thermoplastic resin, UV-curable resin, or a combination thereof. The first molding layer 140 may include, for example, an EMC.

The second redistribution structure 150 may be disposed on the first molding layer 140 and the plurality of conductive posts 133. The second redistribution structure 150 may include the second redistribution pattern 151 and a second redistribution insulating layer 153. The second redistribution pattern 151 may include a plurality of second redistribution lines and a plurality of second redistribution vias. The second redistribution line may have a structure that is substantially the same as or similar to that of the first redistribution line of the first redistribution pattern 111, and the second redistribution via may have a structure that is substantially the same as or similar to that of the first redistribution via of the first redistribution pattern 111. The second redistribution via may connect the second redistribution lines at different vertical levels to each other or connect a portion of the lowermost second redistribution line among the second redistribution lines and the conductive post 133. The second redistribution insulating layer 153 may surround the second redistribution pattern 151.

The second redistribution pattern 151 may include substantially the same material as the first redistribution pattern 111, and the second redistribution insulating layer 153 may include substantially the same material as the first redistribution insulating layer 113.

Referring to FIG. 1, in the resultant product of FIG. 3, a second redistribution pad 155 may be formed on the second redistribution structure 150 (P120). Hereinafter, a method of forming (P120) the second redistribution pad 155 is explained in detail with reference to FIGS. 2, 3, 4, 5A, 5B, 6A, 6B, 7, 8A, 8B, and 9-11,

Referring to FIGS. 2 and 4, a hole 153H may be formed in the first redistribution insulating layer 153 to expose an upper surface of the uppermost second redistribution pattern 151 (P121). The hole 153H may extend in a vertical direction (Z direction) from the upper surface of the second redistribution structure 150 (see FIG. 4) toward the upper surface of the uppermost second redistribution pattern 151. The hole 153H may have a tapered shape in which a horizontal width thereof decreases in a direction from the top of the second redistribution structure 150 (see FIG. 4) toward the upper surface of the uppermost second redistribution pattern 151, but the inventive concept is not limited thereto.

Referring to FIGS. 2 and 5A, in the resultant product of FIG. 4, a seed layer 1551 covering a surface of the second redistribution insulating layer 153 and a surface of the second redistribution pattern 151 exposed by the hole 153H may be formed (P122). In example embodiments, the seed layer 1551 may include copper (Cu), aluminum (Al), silver (Ag), gold (Au), tungsten (W), titanium (Ti), or a combination thereof. Next, a photoresist composition PR may be formed on the seed layer 1551 (P122).

Referring to FIG. 5B, the photoresist composition PR may include a first photoinitiator PI1, a second photoinitiator PI2, a first crosslinking agent CL1, a second crosslinking agent CL2, binder resin BP, a low-molecular weight material PM, and an additive AD.

The first photoinitiator PI1 and the second photoinitiator PI2 may each receive light of a specific wavelength irradiated to the photoresist composition PR to initiate a crosslinking reaction by the first crosslinking agent CL1 and the second crosslinking agent CL2. For example, the first photoinitiator PI1 may initiate a reaction in which the first crosslinking agent CL1 and the binder resin BP are mutually crosslinked by receiving the first light PL1, and the second photoinitiator PI2 may initiate a reaction in which the second crosslinking agent CL2 mutually crosslinks the binder resin BP or a reaction in which the binder resin BP and a low-molecular weight material PM are mutually crosslinked by receiving the second light PL2 having a wavelength different from the first light PL1.

In example embodiments, the first photoinitiator PI and the second photoinitiator PI2 may include at least one substance selected from the group consisting of Hydroxyacetophenone, Alkyl-aminoacetophenone, Benzil ketal, dialkoxyacetophenone, Benzoin ether, Phosphine oxide, Acyloximino ester, 2,2′-Bis(2-chlorophenyl)-4,4′,5,5′-tetraphenyl-1,2′-biimidazole(BCIM), HABI, Photoacid generator, Alpha-haloacetophenone, Trichloromethyl-S-triazines, Photobase generator, Benzophenone, Substituted benzophenone, Thioxanthone, Anthraquinone, Benzoylformate ester, and Camphorquinone. For example, the first photoinitiator PI1 may include hydroxy acetophetone, and the second photoinitiator PI2 may include a photoacid generator.

The first crosslinking agent CL1 may mutually crosslink each of the binder resins BP by the first photoinitiator PI1 that receives the first light PL1, and the second crosslinking agent CL2 may mutually crosslink each of the binder resins BP and the low-molecular weight material PM by the second photoinitiator PI2 that receives the second light PL2.

In example embodiments, the first crosslinking agent CL1 and the second crosslinking agent CL2 may each include at least one material selected from the group consisting of melamine, amino resin, glycoluryl compound, and bisepoxy compound. For example, the first crosslinking agent CL1 and the second crosslinking agent CL2 may each include at least one material selected from the group consisting of etherified amino resin, a methylated melamine such as N-methoxymethyl-melamine, a butylated melamine such as N-butoxymethyl-melamine, methylated urea resin such as Cymel U-65 resin, butylated urea resin such as UFR 80 Resin, a glycoluryl derivative, a bis(hydroxymethyl)-p-cresol compound, etc.

The binder resin BP may be, for example, acrylic binder resin. The acrylic binder resin may include, for example, polybenzyl methacrylate, (meth)acrylic acid/benzyl methacrylate copolymer, (meth)acrylic acid/benzyl methacrylate/styrene copolymer, (meth)acrylic acid/benzyl methacrylate/2-hydroxyethyl methacrylate copolymer, (meth)acrylic acid/benzyl methacrylate/styrene/2-hydroxyethyl methacrylate copolymer, or a combination thereof.

The low-molecular weight material PM may be a monomer or oligomer constituting the binder resin BP but may be defined as a material that is not polymerized and remains in a monomer or oligomer state. For example, when the binder resin BP includes a (meth)acrylic acid/benzyl methacrylate copolymer, the low-molecular weight material PM may include a benzyl methacrylate monomer or a methacrylic acid monomer.

The additive AD may include, for example, surfactants, additives, etc. The surfactant may prevent the coating property of the photoresist composition PR from being deteriorated. The surfactant may include, for example, an alkylbenzenesulfonic acid salt, an alkylpyridinium salt, polyethylene glycol, a quaternary ammonium salt, or a combination thereof, but is not limited thereto. The additive AD may prevent stains or spots when coating the photoresist composition PR. The additive AD may include, for example, malonic acid, 3-amino-1,2-propanediol, a leveling agent, a radical polymerization initiator, or a combination thereof, but is not limited thereto.

In example embodiments, the photoresist composition PR may be a negative-type photoresist material.

Referring to FIGS. 2, 6A, and 6B, in the resultant products of FIGS. 5A and 5B, the first light PL1 may be irradiated to the photoresist composition PR using the photo mask MK formed on the non-exposed area NEA (P123). At this time, the first light PL1 may be irradiated only to the exposed area EA and not to the non-exposed area NEA. Accordingly, the photoresist composition PR including a negative-type photoresist material is cured in the exposed area EA where the first light PL1 is irradiated, but curing may not occur in the non-exposed area NEA where the first light PL1 is not irradiated.

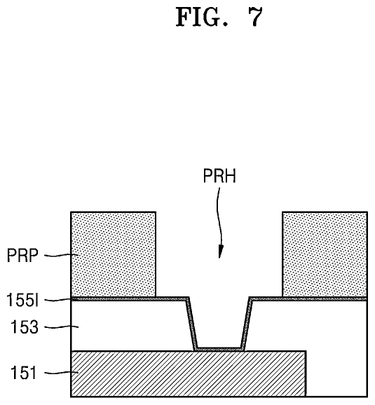

In detail with reference to FIG. 6B, the first photoinitiator PI1 (see FIG. 5B) in the exposed area EA may initiate a crosslinking reaction between each of the binder resins BP by the first crosslinking agent CL1 by receiving the first light PL1 irradiated to the exposed area EA. By the crosslinking reaction, the photoresist composition PR in the exposed area EA may be cured. On the other hand, the first photo initiator PI1 (see FIG. 5B) in the non-exposed area NEA may not receive the first light PL1 due to the photo mask MK. Accordingly, the first photoinitiator PI1 (see FIG. 5B) in the non-exposed area NEA may not initiate a crosslinking reaction, and the photoresist composition PR in the non-exposed area EA may not be cured. Because the photoresist composition PR in the exposed area EA is cured but the photoresist composition PR in the non-exposed area NEA is not cured, the photoresist composition PR to which the first light PL1 is irradiated may have high resolution. Accordingly, in a process to be described below with reference to FIGS. 2 and 7, the photoresist pattern PRP may be faithfully implemented as intended.

Referring to FIGS. 2 and 7, in the resultant products of FIGS. 6A and 6B, the photoresist composition PR (FIG. 6A) in the exposed area EA (FIG. 6A) to which the first light PL1 is irradiated is developed, and thus, the photoresist pattern PRP may be formed (P124).

The photoresist pattern PRP formed through the development process may have a pattern hole PRH formed by removing the photoresist composition PR in the non-exposed area NEA (see FIG. 6A). The pattern hole PRH may expose a surface of a seed layer 1551. The pattern hole PRH may overlap a second redistribution pad 155 to be formed in a process to be described below in the vertical direction (Z direction).

Referring to FIGS. 2, 8A, and 8B, in the resultant product of FIG. 7, the second light PL2 may be irradiated to the photoresist pattern PRP (P125). At this time, the photoresist pattern PRP including a negative-type photoresist material may be cured by being irradiated with the second light PL2.

In detail, referring to FIG. 8B, the second photoinitiator PI2 (see FIG. 6B) included in the photoresist pattern PRP may initiate, by receiving the second light PL2, a crosslinking reaction between each of the binder resins BP by the second crosslinking agent CL2 or initiate a crosslinking reaction between the low molecular weight material PM and the binder resin BP by the second crosslinking agent CL2. Because the photoresist pattern PRP is cured by the second light PL2, the cured photoresist pattern PRP may have excellent chemical resistance even at a relatively high processing temperature.

In example embodiments, the second light PL2 may have a different wavelength from the first light PL1. For example, the first light PL1 may have a wavelength in a range from about 355 nm to about 375 nm, and the second light PL2 may have a wavelength in a range from about 390 nm to about 450 nm. However, aspects of the inventive concept are not limited thereto. Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

In example embodiments, the pattern hole PRH of the photoresist pattern PRP after process P124 described with reference to FIGS. 2 and 7 is performed may be maintained the same even after process P125 described with reference to FIGS. 2, 8A, and 8B is performed. Accordingly, the pattern hole PRH of the photoresist pattern PRP after process P124 described with reference to FIGS. 2 and 7 is performed may have the same horizontal width as the pattern hole PRH of the photoresist pattern PRP after process P125 described with reference to FIGS. 2, 8A, and 8B is performed.

In example embodiments, a vertical length PRD of the photoresist pattern PRP after the second light PL2 is irradiated thereto may be about 5 μm or more. For example, the vertical length PRD of the photoresist pattern PRP after the second light PL2 is irradiated may be about 5.5 μm. If the vertical length PRD of the photoresist pattern PRP after irradiation of the second light PL2 is less than about 5 μm, the photoresist pattern PRP may not secure a sufficient vertical length PRD, and thus, a first metal layer 155a, a second metal layer 155b, and a third metal layer 153c may not be formed properly in a process to be performed later.

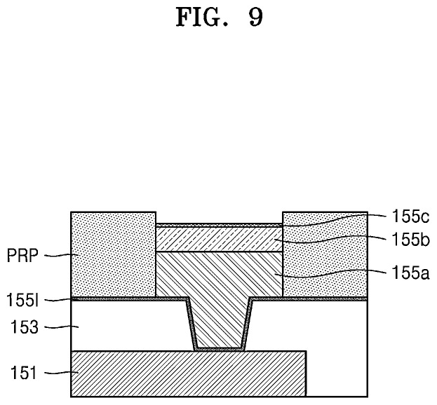

Referring to FIGS. 2 and 9, in the resultant products of FIGS. 8A and 8B, the first metal layer 155a, the second metal layer 155b, and the third metal layer 155a may be sequentially formed on the seed layer 1551 using the photoresist pattern PRP to which the second light PL2 is irradiated (P126). For example, the first metal layer 155a, the second metal layer 155b, and the third metal layer 155c are not formed using different photoresist patterns but may be formed on the seed layer 1551 using only a photoresist pattern PRP to which the second light PL2 is irradiated.

The first metal layer 155a, the second metal layer 155b, and the third metal layer 155c may be formed, for example, through a deposition process. The deposition process may be, for example, a chemical vapor deposition process or a physical vapor deposition process, but is not limited thereto.

In example embodiments, the processes of forming the second metal layer 155b and the third metal layer 155c may each be performed at a relatively higher process temperature than the process of forming the first metal layer 155a. For example, the processes of forming the second metal layer 155b and the third metal layer 155c may be each performed at a process temperature of about 100° C., and the process of forming the first metal layer 155a may be performed at a process temperature of about 40° C. At this time, because the photoresist pattern PRP is cured by the irradiation of the second light PL2 (FIG. 8A) even if the processes of forming the second metal layer 155b and the third metal layer 155c are performed at a relatively high process temperature, defects in the photoresist pattern PRP, such as swelling or leaching, may be prevented.

In example embodiments, the first metal layer 155a, the second metal layer 155b, and the third metal layer 155c may each include any one of copper (Cu), aluminum (Al), silver (Ag), gold (Au), tungsten (W), nickel (Ni), and titanium (Ti). For example, the first metal layer 155a may include copper (Cu), the second metal layer 155b may include nickel (Ni), and the third metal layer 155c may include gold (Au).

Referring to FIGS. 2, 10, and 11, in the resultant product of FIG. 9, after the photoresist pattern PRP (see FIG. 9) is removed, a portion of the seed layer 1551 that overlaps the photoresist pattern PRP (see FIG. 9) in the vertical direction (Z direction) may be removed (P127). At this time, the portion of the seed layer 1551 that overlaps the first metal layer 155a, the second metal layer 155b, and the third metal layer 155c in the vertical direction (Z direction) may remain without being removed, and the first metal layer 155a, the second metal layer 155b, the third metal layer 155c, and the seed layer 1551 remaining without being removed may constitute the second redistribution pad 155.

The photoresist pattern PRP (see FIG. 9) may be removed, for example, by a strip process. A portion of the seed layer 1551 that overlaps the photoresist pattern PRP (see FIG. 9) in the vertical direction (Z direction) may be removed by, for example, an etching process.

In example embodiments, a side surface 155aS of the first metal layer 155a, a side surface 155bs of the second metal layer 155b, and a side surface 155cS of the third metal layer 155c may be aligned with each other on the same plane (i.e., coplanar) in the vertical direction (Z direction). This is because, as described with reference to FIG. 9, the first metal layer 155a, the second metal layer 155b, and the third metal layer 155c are not formed using two or more photoresist patterns formed using two or more types of photoresist compositions but are formed using a single photoresist pattern PRP. Terms such as “same,” “equal,” “planar,” or “coplanar,” as used herein encompass identicality or near identicality including variations that may occur, for example, due to manufacturing processes. The term “substantially” may be used herein to emphasize this meaning, unless the context or other statements indicate otherwise.

In example embodiments, a pitch 155P of the second redistribution pad 155 may be about m or less. For example, the pitch 155P of the second redistribution pad 155 may be in a range from about 10 μm to about 45 μm.

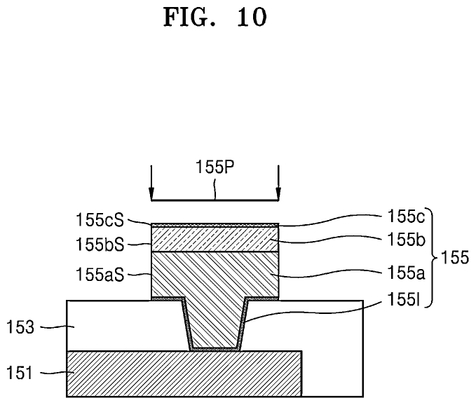

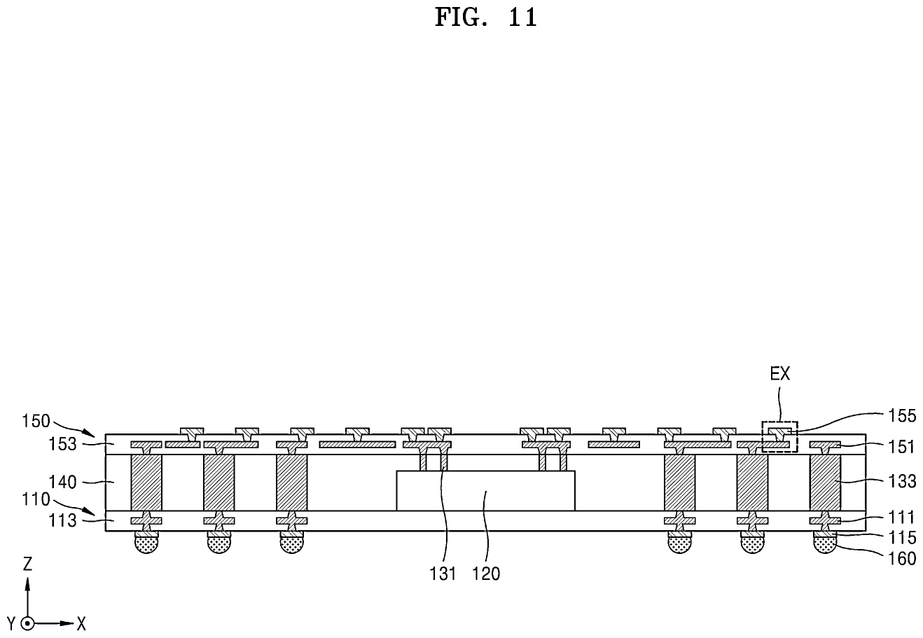

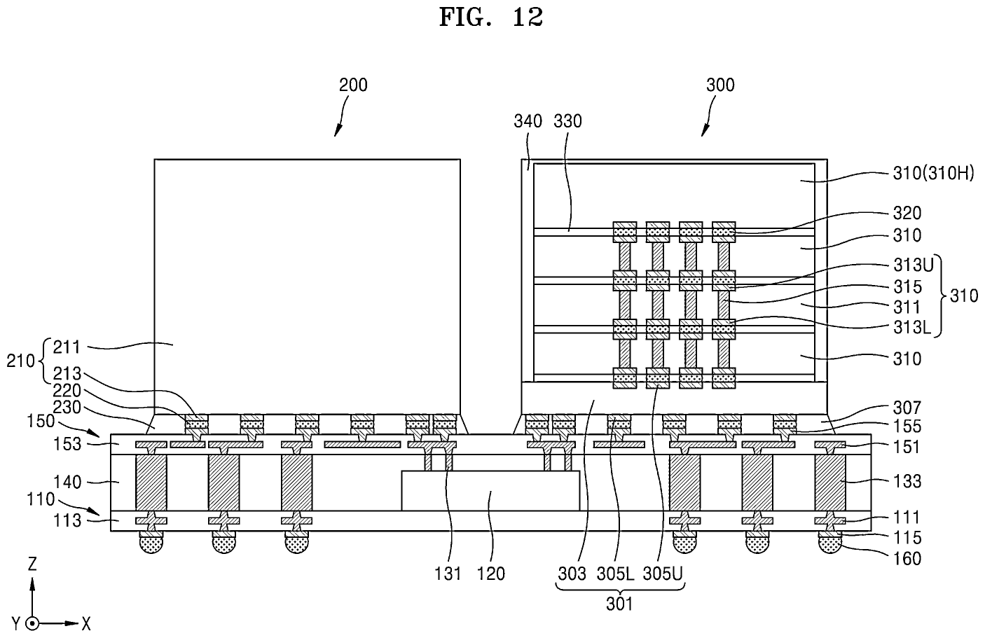

Referring again to FIGS. 1 and 12, in the resultant products of FIGS. 10 and 11, the first semiconductor device 200 and the second semiconductor device 300 are provided on the second redistribution structure 150, and the first semiconductor device 200 and the second semiconductor device 300 may each be connected to the second redistribution structure 150 (P130). The first semiconductor device 200 and the second semiconductor device 300 may be arranged to be horizontally spaced apart from each other on the second redistribution structure 150.

The first semiconductor device 200 may include a first semiconductor chip 210. The first semiconductor chip 210 may be, for example, a logic chip. The logic chip may be a microprocessor. For example, the logic chip may be a central processing unit (CPU), a controller, an application specific integrated circuit (ASIC), etc.

The first semiconductor chip 210 may include a first semiconductor substrate 211 and a plurality of first chip pads 213. The first semiconductor substrate 211 may include a semiconductor element, such as Si or Ge, or a compound semiconductor, such as SiC, GaAs, InAs, or InP. The first semiconductor substrate 211 may include a conductive region, for example, a well doped with an impurity, or a structure doped with an impurity. The first semiconductor substrate 211 may have various device isolation structures, such as a shallow trench isolation (STI) structure.

The first semiconductor substrate 211 may include an active surface and an inactive surface facing the active surface. For example, the active surface may be a lower surface of the first semiconductor substrate 211 on which the first chip pad 213 is disposed, and the inactive surface may be an upper surface of the first semiconductor substrate 211 facing the lower surface of the first semiconductor substrate 211.

The active surface of the first semiconductor substrate 211 may include a plurality of various types of individual devices. For example, the plurality of individual devices may include various microelectronic devices, such as a complementary metal-oxide semiconductor (CMOS) transistor, a metal-oxide-semiconductor filed effect transistor (MOSFET), a large system integration (LSI), an image sensor such as a CMOS imaging sensor (CIS), a micro-electro-mechanical system (MEMS), an active device, a passive device, etc.

The plurality of individual devices may be electrically connected to the conductive region of the first semiconductor substrate 211. Each of the plurality of individual devices may be electrically insulated from other neighboring individual devices by an insulating layer (not shown).

The first chip pad 213 may be disposed on the lower surface of the first semiconductor substrate 211. The first chip pad 213 may be electrically connected to a plurality of various types of individual devices included in the active surface of the first semiconductor substrate 211.

A plurality of first connection terminals 220 may be disposed between the first semiconductor device 200 and the second redistribution structure 150. Each of the plurality of first connection terminals 220 may electrically connect the second redistribution pad 155 of the second redistribution structure 150 to the first chip pad 213 of the first semiconductor chip 210. For example, the plurality of first connection terminals 220 may each include at least one of solder, tin (Sn), silver (Ag), copper (Cu), and aluminum (Al).

A first underfill layer 230 may fill between the first semiconductor device 200 and the second redistribution structure 150 and may surround the plurality of first connection terminals 220. The first underfill layer 230 may include, for example, an epoxy resin.

The second semiconductor device 300 may include a second semiconductor chip 301, a plurality of third semiconductor chips 310, and a second molding layer 340. For example, the second semiconductor chip 301 may be a buffer chip for controlling the plurality of third semiconductor chips 310. For example, each of the plurality of third semiconductor chips 310 may be a high bandwidth memory (HBM) dynamic random access memory (DRAM) chip, and the second semiconductor chip 301 may be a buffer chip for controlling the HBM DRAM chip.

In example embodiments, the horizontal area of the second semiconductor chip 301 may be greater than the horizontal area of each of the plurality of third semiconductor chips 310.

The second semiconductor chip 301 may include a second semiconductor substrate 303, a second lower pad 305L, and a second upper pad 305U. The second semiconductor substrate 303 may include a material that is substantially the same as or similar to that of the first semiconductor substrate 211 and may have a structure that is substantially the same as or similar to that of the first semiconductor substrate 211. However, aspects of the inventive concept are not limited thereto.

The second lower pad 305L may be disposed on a lower surface of the second semiconductor substrate 303, and the second upper pad 305U may be disposed on an upper surface of the second semiconductor substrate 303. The second lower pad 305L and the second upper pad 305U may each include copper (Cu).

A plurality of third semiconductor chips 310 may be disposed on the second semiconductor chip 301. The plurality of third semiconductor chips 310 may be stacked in the vertical direction (Z direction) on the second semiconductor chip 301, respectively. In FIG. 12, the plurality of third semiconductor chips 310 are illustrated as including four third semiconductor chips 310, but aspects of the inventive concept are not limited thereto.

The plurality of third semiconductor chips 310, excluding an uppermost third semiconductor chip 310H, may respectively include a third semiconductor substrate 311, a third lower pad 313L, a third upper pad 313U, and a through electrode 315, and the uppermost third semiconductor chip 310H may include the third semiconductor substrate 311 and the third lower pad 313L. For example, the uppermost third semiconductor chip 310H may not include the second upper pad 313U and the through electrode 315.

The third semiconductor substrate 311 may include a material that is substantially the same as or similar to that of the first semiconductor substrate 211 and may have a structure that is substantially the same or similar to that of the first semiconductor substrate 211. However, aspect of the inventive concept are not limited thereto.

The through electrode 315 may extend in the vertical direction (Z direction) through the third semiconductor substrate 311. The through electrodes 315 may be horizontally spaced apart from each other. The through electrode 315 may overlap the third lower pad 313L and the third upper pad 313U in the vertical direction (Z direction). The through electrode 315 may connect the third lower pad 313L to the third upper pad 313U.

The third lower pad 313L may be disposed on a lower surface of the second semiconductor substrate 303, and the third upper pad 313U may be disposed on an upper surface of the second semiconductor substrate 303. The third lower pad 313L and the third upper pad 313U may each include copper (Cu).

A plurality of second connection terminals 320 may be disposed between the second semiconductor device 300 and the second redistribution structure 150, between the second semiconductor chip 301 and the lowermost third semiconductor chip 310, and between each of the plurality of third semiconductor chips 310. The plurality of second connection terminals 320 may electrically connect the second semiconductor device 300 to the second redistribution structure 150, the second semiconductor chip 301 to the lowermost third semiconductor chip 310, and each of the plurality of third semiconductor chips 310. Each of the plurality of second connection terminals 320 may include a material that is substantially the same as or similar to that of the first connection terminal 220.

A second underfill layer 307 may fill a space between the second semiconductor device 300 and the second redistribution structure 150 and surround the plurality of second connection terminals 320. A third underfill layer 330 may fill a space between the second semiconductor chip 301 and the lowermost third semiconductor chip 310 and between each of the plurality of third semiconductor chips 310 and may surround the plurality of second connection terminals 320 disposed between the second semiconductor chip 301 and the lowermost third semiconductor chip 310 and between each of the plurality of third semiconductor chips 310. The second underfill layer 307 and the third underfill layer 330 may include, for example, epoxy resin.

The second molding layer 340 may surround the plurality of third semiconductor chips 310. For example, the second molding layer 340 may surround side surfaces of each of the plurality of third semiconductor chips 310 and cover an upper surface of the uppermost third semiconductor chip 310H. However, aspects of the inventive concept are not limited thereto. The second molding layer 340 may include, for example, an EMC.

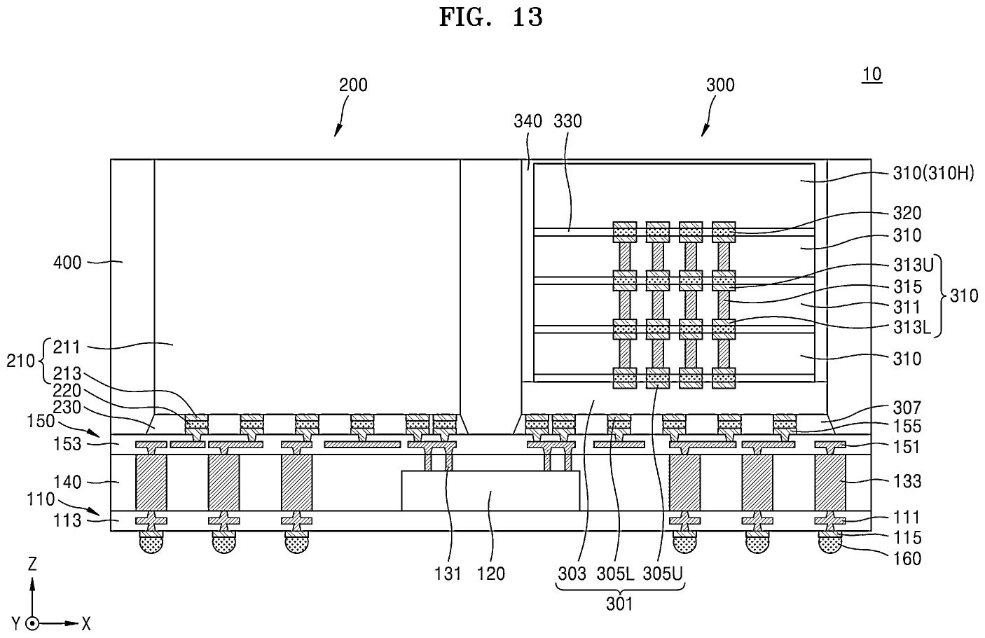

Referring to FIGS. 1 and 13, in the resultant product of FIG. 12, a third molding layer 400 surrounding the first semiconductor device 200 and the second semiconductor device 300 may be formed (P140). For example, the third molding layer 400 may surround a side of the first semiconductor device 200 and a side of the second semiconductor device 300 but may not cover an upper surface of the first semiconductor device 200 and an upper surface of the second semiconductor device 300. Accordingly, the upper surface of the third molding layer 400 may be at the same vertical level as the upper surface of the first semiconductor device 200 and the upper surface of the second semiconductor device 300.

In other examples, the third molding layer 400 may surround the side of the first semiconductor device 200 and the side of the second semiconductor device 300 and may cover the upper surface of the first semiconductor device 200 and the upper surface of the second semiconductor device 300. Accordingly, an upper surface of the third molding layer 400 may be at a vertical level that is higher than the upper surfaces of the first and second semiconductor devices 200 and 300.

By forming the third molding layer 400, the semiconductor package 10 according to embodiments may be manufactured.

The second redistribution pad 155 of the semiconductor package 10 according to embodiments may include the first metal layer 155a, the second metal layer 155b, and the third metal layer 155c, which are formed using a single photoresist pattern PRP. At this time, the photoresist pattern PRP may be formed by sequentially irradiating first light PL1 and second light PL2 to a photoresist composition PR including at least one first crosslinking agent CL1 and at least one first photoinitiator PI1 that react with the first light PL1 and at least one second crosslinking agent CL2 and at least one second photoinitiator PI2 that react with the second light PL2 having a different wavelength from that of the first light PL1. Because the photoresist composition PR includes two or more types of crosslinking agents and two or more types of photoinitiators that react with light of different wavelengths, the photoresist composition PR may have excellent resolution and excellent chemical resistance even at a relatively high processing temperature. Therefore, the photoresist pattern PRP may be used not only in the formation process of the first metal layer 155a but also in the formation processes of the second metal layer 155b and the third metal layer 155c, which are performed at a relatively high process temperature. Accordingly, it is unnecessary to form a separate photoresist pattern for use in the formation processes of the second metal layer 155b and third metal layer 155c, which are performed at a relatively high process temperature, and thus, the efficiency of the formation process of the second redistribution pad 155 is improved and the second redistribution pad 155 with improved structural reliability may be formed.

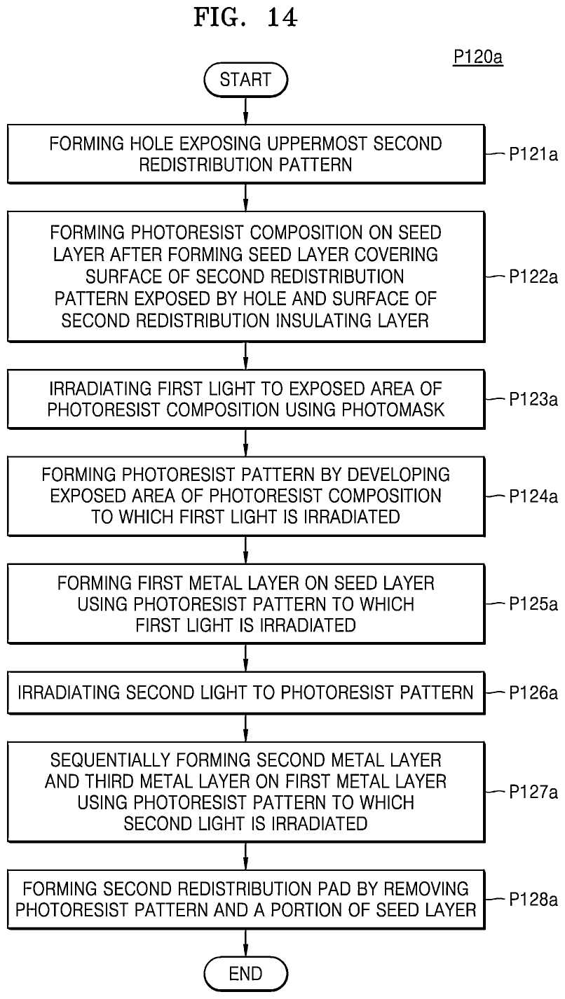

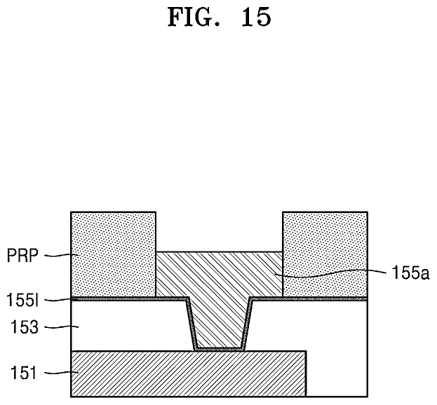

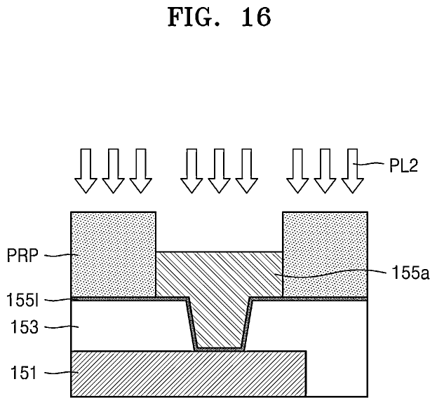

FIG. 14 is a flowchart illustrating a method (P120a) of forming a redistribution pad, according to embodiments. FIGS. 15 and 16 are diagrams illustrating each step of the method (P120a) of forming the redistribution pad, according to embodiments. The method (P120a) of forming a redistribution pad illustrated in FIG. 14 may be performed after process P110 illustrated in FIG. 1 instead of the method (P120) of forming a redistribution pad illustrated in FIGS. 1 and 2, and process P121a, process P122a, process P123a, process P124a, and process P128a of the method (P120a) of forming the redistribution pad illustrated in FIG. 14 are substantially the same as process P121, process P122, process P123, process P124, and process P127 of the method (P120) of forming the redistribution pad described with reference to FIGS. 2, 4, 5A, 5B, 6A, 6B, 7, 9, 10, and 11, respectively, and thus, the descriptions thereof are omitted.

Referring to FIGS. 14 and 15, in the resultant product of process P124a, the first metal layer 155a may be formed on the seed layer 1551 using the photoresist pattern PRP to which the first light PL1 (see FIG. 6A) is irradiated (P125a). Because the formation process of the first metal layer 155a is performed at a relatively low process temperature, even if the photoresist pattern PRP is not irradiated by the second light PL2 (see FIG. 16), defects, such as swelling or leaching in the photoresist pattern PRP, may not occur during the formation process of the first metal layer 155a.

Referring to FIGS. 14 and 16, in the resultant product of FIG. 15, the second light PL2 may be irradiated to the photoresist pattern PRP (P126a). In example embodiments, the second light PL2 may be irradiated to the photoresist pattern PRP and the first metal layer 155a. In other embodiments, the second light PL2 may be irradiated only to the photoresist pattern PRP. In this case, unlike the example illustrated in FIG. 16, the second light PL2 may be irradiated to the photoresist pattern PRP using a photomask formed on the first metal layer 155a. When the second light PL2 is irradiated to the photoresist pattern PRP, the photoresist pattern PRP may be cured as described with reference to FIGS. 8A and 8B.

Next, in the resultant products of FIGS. 14 and 16, the second metal layer 155b and the third metal layer 155c may be sequentially formed on the first metal layer 155a using the photoresist pattern PRP to which the second light PL2 is irradiated (P127a). By performing process P128a, the second redistribution pad 155 (see FIG. 10) may be formed.

While aspects of the inventive concept have been particularly shown and described with reference to embodiments thereof, it will be understood that various changes in form and details may be made therein without departing from the spirit and scope of the following claims.

What is claimed is:

1. A method of forming a redistribution pad, the method comprising:
forming a hole in a redistribution insulating layer to expose a redistribution pattern;
forming a photoresist composition on a surface of the redistribution insulating layer and filling the hole, the photoresist composition including at least one first photoinitiator and at least one first crosslinking agent that cause a crosslinking reaction by a first light and at least one second photoinitiator and at least one second crosslinking agent that cause a crosslinking reaction by a second light having a different wavelength from the first light;
irradiating the first light to the photoresist composition;
forming a photoresist pattern having a pattern hole using the photoresist composition to which the first light is irradiated;
irradiating the second light to the photoresist pattern; and
forming the redistribution pad by using the photoresist pattern to which the second light is irradiated.

2. The method of claim 1, wherein
the forming of the redistribution pad includes sequentially forming a first metal layer, a second metal layer, and a third metal layer on the redistribution pattern using the photoresist pattern to which the second light is irradiated.

3. The method of claim 2, wherein the forming of the second metal layer and the forming of the third metal layer are performed at a process temperature that is higher than that of the forming of the first metal layer.

4. The method of claim 2, wherein side surfaces of each of the first metal layer, the second metal layer, and the third metal layer are on the same plane in a vertical direction.

5. The method of claim 1, wherein the photoresist composition includes a negative-type photoresist composition.

6. The method of claim 1, wherein a vertical length of the photoresist pattern to which the second light is irradiated is 5 μm or more.

7. The method of claim 1, further comprising:
after forming the hole in the redistribution insulating layer, forming a seed layer covering a surface of the redistribution insulating layer and a surface of the redistribution pattern exposed by the hole.

8. The method of claim 1, wherein
the first photoinitiator and the second photoinitiator each include at least one selected from a group consisting of hydroxyacetophetone, alkylaminoacetophetone, benzyl ketal, dialkoxyacetophenone, benzoin ether, phosphine oxide, acyloxymino ester, BCIM, a hexaarylbis.Imidazole compound, a photoacid generator, alphahaloacetophenone, trichloromethyl-S-triazine, a photobase generator, benzophenone, substituted benzophenone, thioxanthone, anthraquinone, benzoylformate ester, and camphor quinone.

9. The method of claim 1, wherein
the first crosslinking agent and the second crosslinking agent each include at least one selected from a group consisting of melamine, an amino resin, a glycoluryl compound, and a bisepoxy compound.

10. The method of claim 1, wherein a pitch of the redistribution pad is about 45 μm or less.

11. The method of claim 1, wherein
a horizontal width of the pattern hole of the photoresist pattern before the second light is irradiated to the photoresist pattern is the same as a horizontal width of the pattern hole of the photoresist pattern after the second light is irradiated to the photoresist pattern.

12. A method of forming a redistribution pad, the method comprising:
forming a hole exposing a redistribution pattern in a redistribution insulating layer;
forming a photoresist composition on a surface of the redistribution insulating layer and filling the hole, the photoresist composition including at least one first photoinitiator and at least one first crosslinking agent that cause a crosslinking reaction by a first light and at least one second photoinitiator and at least one second crosslinking agent that cause a crosslinking reaction by a second light having a different wavelength from the first light;
irradiating the first light to the photoresist composition;
forming a photoresist pattern having a pattern hole using the photoresist composition to which the first light is irradiated;
forming a first metal layer on the redistribution pattern using the photoresist pattern, wherein the first metal layer constitutes a first portion of the redistribution pad;
irradiating the second light to the photoresist pattern; and
forming a second metal layer and a third metal layer on the first metal layer using the photoresist pattern to which the second light is irradiated, wherein the second metal layer and the third metal layer constitute a second portion of the redistribution pad.

13. The method of claim 12, wherein the forming of the second metal layer and the forming of the third metal layer are performed at a process temperature that is higher than that of the forming of the first metal layer.

14. The method of claim 12, wherein side surfaces of each of the first metal layer, the second metal layer, and the third metal layer are on the same plane in a vertical direction.

15. The method of claim 12, wherein the photoresist composition includes a negative-type photoresist composition.

16. The method of claim 12, wherein
the first photoinitiator and the second photoinitiator each include at least one selected from a group consisting of hydroxyacetophetone, alkylaminoacetophetone, benzyl ketal, dialkoxyacetophenone, benzoin ether, phosphine oxide, acyloxymino ester, BCIM, a hexaarylbis.Imidazole compound, a photoacid generator, alphahaloacetophenone, trichloromethyl-S-triazine, a photobase generator, benzophenone, substituted benzophenone, thioxanthone, anthraquinone, benzoylformate ester, and camphor quinone, and
the first crosslinking agent and the second crosslinking agent each include at least one selected from a group consisting of melamine, an amino resin, a glycoluryl compound, and a bisepoxy compound.

17. The method of claim 11, further comprising:
after forming the hole in the redistribution insulating layer, forming a seed layer covering a surface of the redistribution insulating layer and a surface of the redistribution pattern exposed by the hole.

18. A method of forming a redistribution pad, the method comprising:
forming a hole exposing a redistribution pattern in a redistribution insulating layer;
forming a seed layer covering a surface of the redistribution insulating layer and a surface of the redistribution pattern exposed by the hole;
forming, on the seed layer, a photoresist composition including at least one first photoinitiator and at least one first crosslinking agent that cause a crosslinking reaction by a first light having a wavelength in a range from 355 nm to 375 nm, and at least one second photoinitiator and at least one second crosslinking agent that cause a crosslinking reaction by a second light having a wavelength in a range from 390 nm to 450 nm;
irradiating the first light to the photoresist composition;
forming a photoresist pattern having a pattern hole using the photoresist composition to which the first light is irradiated;
irradiating the second light to the photoresist pattern; and
forming the redistribution pad using the photoresist pattern to which the second light is irradiated, wherein the redistribution pad includes a first metal layer including copper, a second metal layer including nickel, and a third metal layer including gold.

19. The method of claim 18, wherein
side surfaces of each of the first metal layer, the second metal layer, and the third metal layer are on the same plane in a vertical direction.

20. The method of claim 18, wherein
the first photoinitiator and the second photoinitiator each include at least one selected from a group consisting of hydroxyacetophetone, alkylaminoacetophetone, benzyl ketal, dialkoxyacetophenone, benzoin ether, phosphine oxide, acyloxymino ester, BCIM, a hexaarylbis.Imidazole compound, a photoacid generator, alphahaloacetophenone, trichloromethyl-S-triazine, a photobase generator, benzophenone, substituted benzophenone, thioxanthone, anthraquinone, benzoylformate ester, and camphor quinone, and
the first crosslinking agent and the second crosslinking agent each include at least one selected from a group consisting of melamine, an amino resin, a glycoluryl compound, and a bisepoxy compound.
